(19) United States
(12) Patent Application Publication
(10) Pub. No.: US 2006/0002099 A1
(43) Pub. Date: Jan. 5, 2006

(54) Electromagnetic shield assembly

(76) Inventors: Edward B. Stoneham, Los Altos, CA (US); Thomas M. Gaudette, Boston, MA (US)

Correspondence Address: KOLISCH HARTWELL, P.C., 520 S.W. YAMHILL STREET, SUITE 200, PORTLAND, OR, 97204, US

(21) Appl. No.: 10/882,886

(22) Filed: Jun. 30, 2004

(51) Int. Cl. H05K 9/00

(52) U.S. Cl. 361/816

(57) ABSTRACT

An example of an electromagnetic (EM) shield assembly may include a top and sides, which together form a chamber configured to house a circuit assembly. The EM shield assembly may include a conductive shield layer and a dielectric layer. The top may include a conductive strip extending along the dielectric layer, while one or more sides may each include a via extending through the dielectric layer. A via may be adapted to provide a connection between a circuit conductor inside or outside the chamber with the conductive strip. In this manner the vias and the conductive strip are capable of forming a continuous circuit path within the EM shield assembly. Alternatively or additionally, some EM shield assemblies may include resistive material included on the interior surface.

### BACKGROUND

Electronic circuit components may be surrounded by shields, or covers, to suppress dangerous or disruptive electromagnetic (EM) radiation created by electronic circuit components at communication frequencies, including radio frequencies. In some environments, electronic components may be enclosed in some form of conductive cover that is connected to a circuit ground. An EM shield may be a solid metal housing or lid shaped to create a chamber enveloping an electronic circuit. EM shields have been developed for use in compact electronic environments that include numerous electronic components on a substrate. In such compact environments, the electronic components may be difficult to isolate from one another using individual encapsulating EM shields. However, shields interfere with communication between the various shielded electronic circuits. In such compact environments it there is a need to provide both effective EM shielding and proper inter circuit communication while maintaining the compact size that is desired in an increasing number of electronic devices.

### BRIEF SUMMARY OF THE DISCLOSURE

An EM shield assembly may include an EM shield, as well as a conductive assembly capable of conducting electrical current as part of a circuit. The EM shield assembly may include a top and sides shaped to form a chamber capable of enclosing one or more circuit assemblies. The EM shield may be formed of laminate, or created by combining multiple layers of materials. Such a laminate EM shield may include conductive strips and vias extending along one or more dielectric layers so as to form the conductive assembly. Some examples, EM shields may alternatively or additionally include a layer of resistive material, such as a resistive film, to provide damping of electronic resonances.

### BRIEF DESCRIPTION OF THE FIGURES

FIG. 1 is a plan view of a circuit structure including an EM shield assembly mounted on a substrate.

FIG. 2 is a cross section taken along line 2-2 of FIG. 1.

FIG. 3 is a cross section taken along line 3-3 of FIG. 2.

FIG. 4 is a cross section taken along line 4-4 of FIG. 2

### DETAILED DESCRIPTION OF VARIOUS EMBODIMENTS

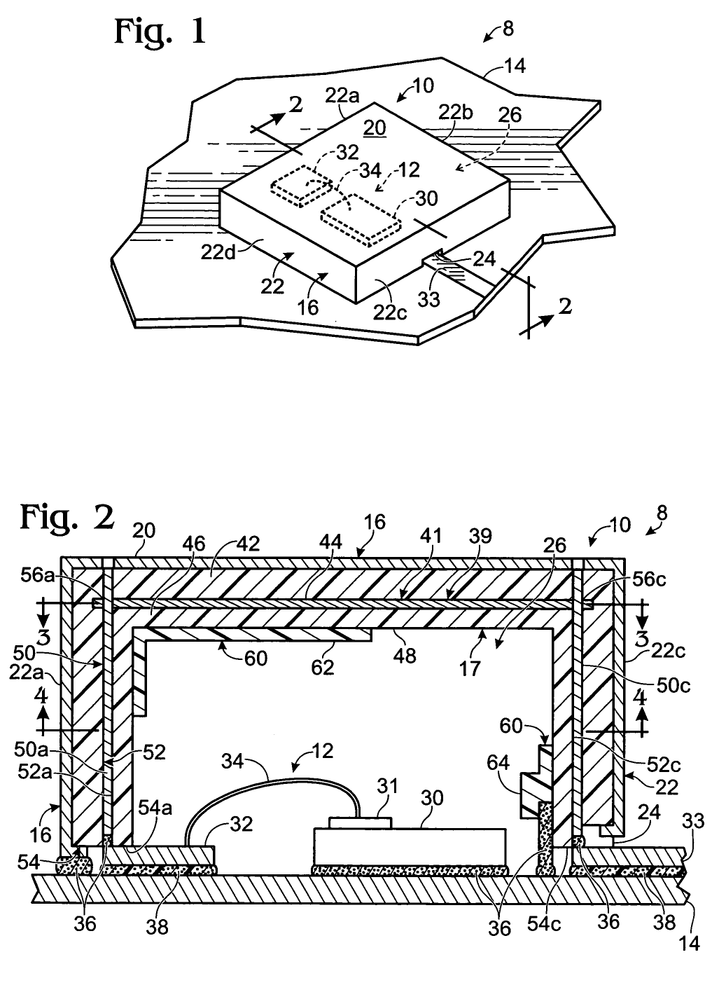

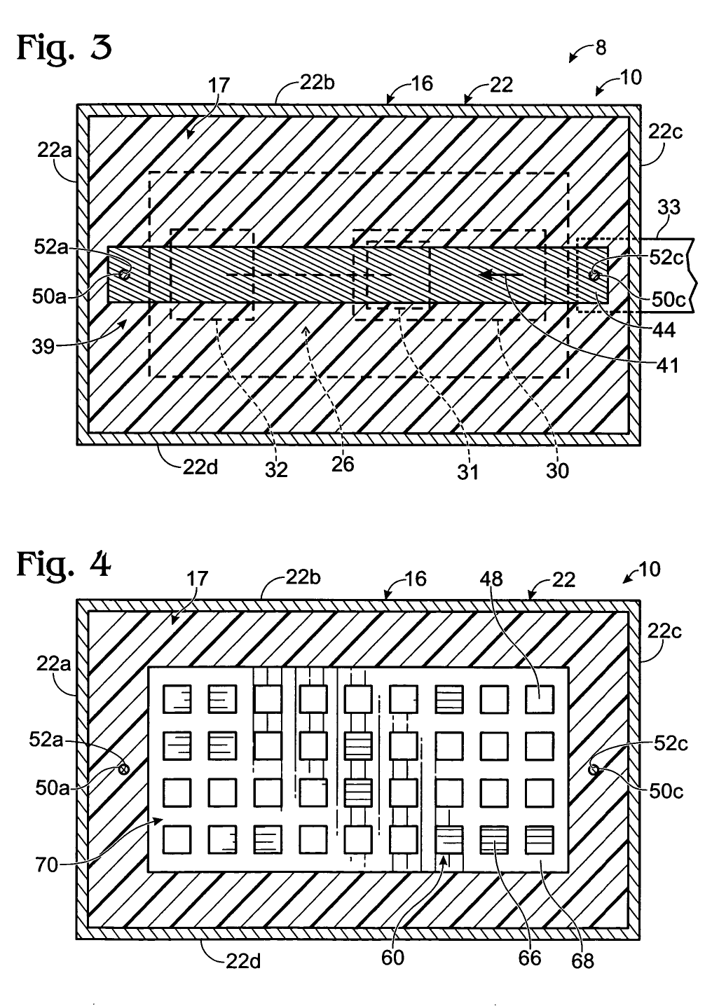

FIGS. 1-4 depict a simplified exemplary circuit structure 8 including an EM shield assembly 10, or cover having various features illustrated in a single composite embodiment for convenience. These features may have various forms, and may be realized in other shield assemblies individually or in various other combinations. As used herein, an EM shield assembly may house one or more circuit assemblies 12 that may individually or in combination form one or more complete circuits, one or more portions of one or more circuits, one or more combinations of elements or components of a circuit, or any combination of circuits, circuit portions, and circuit components, and may include shared circuit portions or components.

In this example, then, EM shield assembly 10 may be mounted to a substrate 14. EM shield assembly 10, also referred to as an enclosure, may include an electromagnetically conductive layer forming a shield 16 having a top 20, and sides 22, such as sides 22a, 22b, 22c, and 22d, forming an enclosed chamber 26. As seen in the cross-section of FIG. 2, the EM shield assembly may be a laminate, or may be composed of multiple layers. Conductive exterior layer 16 may extend along the entire exterior of the EM shield assembly. Shield 16 may be made of an electromagnetically (including electrically or magnetically) conductive material, such as aluminum, copper or other metal, and may be formed of a combination of materials, at least one of which is conductive, such as a conductive layer with a non-conductive (dielectric) or semi-conductive material. Directly adjacent to the shield 16 may be dielectric body 17. Dielectric body 17 may be, further arranged in one or more layers.

The shield 16 may also include one or more openings or cutouts, such as cutout 24, to allow the passage of electric current, such as in the form of signals or power, into or out of the chamber 26 without substantial compromise to the shielding. While only one cutout is illustrated in this example it should be appreciated that EM shield 16 may include more than one cutout and that such cutouts may be located on the top or any side of shield assembly 10. As will be seen, a conductor 33, shown mounted on substrate 14, may pass through cutout 24 to electrically connect circuit assembly 12 with other circuit assemblies or components located outside of the EM shield assembly. Conductor 33 may be a wire, a microstrip line, or any other configuration capable of conducting electrical current.

Shield 16 may protect circuit assemblies, such as assembly 12, enclosed in chamber 26 from environmental and electromagnetic influences and/or isolate the enclosed circuit assemblies. While not shown, a shield 16 may further include an interior wall that can separate chamber 26 into more than one sub-chamber that may be capable of isolating two or more circuit assemblies.

Circuit assembly 12 may include various components. For purposes of illustration, circuit assembly 12 may include respective circuit elements 30 and 32 connected by a suitable interconnect, such as by a bond wire 34. Bond wire may be connected to circuit element 30 by connection to a terminal 31 positioned on the circuit element. Circuit element 30 may include a lumped or distributed element, or combination or network of passive and/or active elements, such as transmission lines, resistors, capacitors, inductors, and semiconductor devices, and may be mounted on a circuit chip having a dielectric, semiconductive or conductive substrate. Furthermore, the circuit assembly 12 may include one or a combination of diodes and transistors in an integrated circuit (IC) or chip, including, for example, a monolithic microwave integrated circuit (MMIC), application specific integrated circuit (ASIC), or the like. For purposes of illustration, circuit element 32 may be an electrical conductor for transmitting a signal or power relative to circuit element 30.

As seen in FIG. 2, the EM shield 16 may be mounted directly to substrate 14 at one or more points. In this example, substrate 14 is conductive and provides a ground for the shield. Other forms of substrate may be used, such as a dielectric with one or more conductive layers. Accordingly, shield 16 may be directly attached to substrate 14 using a conductive adhesive 36. Conductive adhesives may include conductive epoxy, conductive pads, solder, brazing material, deformed metal, z-axis conducting elastomer, or any similar conductive or resistive material. Further, there may be one or more type of conductive adhesive used in the mounting of EM shield assembly 10. It should be noted that shield side 22c may not be directly attached to substrate 14 in the area of cutout 24.

Optionally, EM shield 16 may include one or more electrical ground connectors (not here shown) for grounding the shield 16 to the local circuit ground. These ground connectors may be in the form of metal strips extending from one or more portions of the shield into the substrate, into an adjacent EM shield, or to whatever ground connection is available.

Conductors 32 and 33 may be mounted onto substrate 14 using insulating layers 38. The insulating layers may be in the form of an insulating epoxy or other adhesive, or an insulating pad. These insulating layers isolate the conductors from the conductive substrate. Circuit element 30 of circuit assembly 12 may require that it be grounded, in which case the backside of circuit element 30 may be attached to substrate 14 using conductive adhesive 36.

Shield assembly 10 may further include a conductive assembly 39 supported by a dielectric body 17 relative to shield 16. Conductive assembly 39 may provide a continuous electrical path 41 through the shield assembly. Path 41 may have branches, and multiple paths, whether adapted to carry signals or power. Components of the conductive assembly may extend along a surface of, or be embedded in, dielectric body 17. Dielectric body 17 may be a single layer of dielectric or a plurality of layers of dielectric, which layers may or may not be separated by one or more layers of non-dielectric material. In this example, dielectric body 17 includes first and second dielectric layers 42 and 46. The first and second dielectric layers 42 and 46 may be continuous along EM shield 16, extending along the EM shield top 20 and sides 22a, 22b, 22c, and 22d. Dielectric body 17 may also extend only over one or more portions of shield 16. In some areas, the first and second dielectric layers 42 and 46 may merge into one layer, unseperated by any non-dielectric material. The second dielectric layer 46 may have an interior face 48 that defines chamber 26. Although dielectric layers 42 and 46 are shown extending across the top and down the sides of the EM shield assembly, separate dielectric layers may be used, for instance, to form the portion of the dielectric body making up the sides.

Conductive assembly 39 may include a conductive strip 44 that may extend through or on dielectric body 17. In the configuration shown, the conductive strip 44 is sandwiched between first dielectric layer 42 and second dielectric layer 46. Conductive strip 44 may be composed of any suitable conductive materials including the conductive metals discussed above.

The EM shield sides 22a and 22c may include one or more vias 50, such as vias 50a and 50c, that extend between the first and second dielectric layers 42 and 46. The vias may be formed by drilling, etching, or otherwise creating respective elongated via holes 52, such as holes 52a and 52c. Such via holes, or tunnels, may extend between the first and second dielectric layers 42 and 46, or extend through an individual layer. These via holes may then be filled with electromagnetically conductive material to form the vias.

Vias 50a and 50c may extend the entire height of sides 22a and 22c, as shown. Shield assembly 10 may have a lower edge 54 in contact with substrate 14. Vias 50 a and 50c, accordingly have lower ends positioned near lower edge positions 54a and 54c of the shield assembly, and extend up to contact conductive strip 44 at respective intersection points 56a and 56c. The lower ends of the vias may be connected to signal conductors 32 and 33, respectively, by any suitable means, such as the use of conductive adhesive 36.

Vias 50a and 50b may connect with conductive strip 44 to form conductive assembly 39 within the EM shield assembly 10. Conductive assembly 39 may be capable of being used as part of a circuit. For example, conductive layer 53 may be capable of conducting current or a signal used or generated by circuit element 30 of circuit assembly 12. An electrical current may be conducted from circuit element 30, through terminal 31, bond wire 34, signal conductor 32, via 50a, conductive strip 44, via 50c, and conductor 33. Thus, through conductor 33, a signal or power may flow between circuit assembly 12 and a circuit outside of shielded chamber 26.

FIGS. 1-4 show an embodiment of an EM shield assembly 10 that includes only one conductive strip 44 embedded in shield assembly 10, and which interfaces with vias 52a and 52c at intersection points 56a and 56c, respectively. An EM shield assembly 10 may include more than one conductive strip or conductive assembly, and such strips may further be embedded between more than two isolating dielectric layers or extend on a dielectric layer or body. Similarly, while these figures show vias formed within two sides of the EM shield assembly, such vias may be contained within all or any combination of sides of the shield assembly. Further there may be multiple vias within any one side. Other forms or configurations for realizing a conductive assembly 39 may be used.

The interior surface 48 of EM shield assembly 10 may include portions of resistive material 60 that may be effective in damping undesired electrical propagation within chamber 26. Shielded enclosures such as chamber 26 may have resonances at various frequencies that may interfere with the proper operation of circuit assembly 12 within the chamber 26. Resistive material 60 may decrease or provide damping to such resonances, and a layer of resistive material 60 may extend along all or part of the interior surface 48 of dielectric layer 46. Such resistive material 60 may also be positioned in other ways, such as between layers of dielectric material.

Resistive material 60 may be resistive ink, film, paint, other resistive coating, or a combination thereof. This material may be applied to the surface 48 by silk-screening, stenciling, spraying, squirting, painting, inkjet printing, lithography, or any other convenient method. This resistive material 60 may be applied to the surface 48 according to a pattern of distribution so as to create multiple areas of resistive material 62 and 64.

As shown in FIG. 2, interior shield surface 48 may include a first resistive material area 62 that is uniform and covers a portion of the interior shield surface along both the top 20 and the side 22a of shield 10. This interior surface may also include a second resistive material area 64 that covers only a portion of side 22c. The resistive material may be of uniform thickness or the thickness may vary. Some areas of resistive material may be connected to substrate 14 using conductive adhesive 36.

An alternative embodiment is shown in FIG. 4. As seen in this cross-section, the interior shield surface may be covered with a resistive material 60 that is uniformly patterned. Such a pattern 70 may have a predetermined ratio of open, insulating areas 66 to covered, resistive material areas 68. This resistive material pattern 70 may be applied in a sheet or a film that may include a mesh. Such a film may be defined having an average resistivity of between 10 omhs/square and 1000 omhs/square.

As has been mentioned, the addition of such a layer of resistive materials may result in damping of resonances and extraneous couplings within chamber 26 over a desired range of frequencies. In order to improve this damping, resistive material 60 may be selected according to resistivity, and the thickness and pattern in which the material may be applied. Additionally, damping may be improved by properly selecting the dielectric material included in the first and the second dielectric layers 42 and 46 of shield 20, and the thickness this dielectric material The EM shield assembly 10 may be fabricated from circuit board material, including conductive and dielectric material. Fabrication of the EM shield assembly 10 and/or the substrate 14, or the circuit structure 8 including the EM shield assembly 10, substrate 14, and associated circuitry, such as circuit assembly 12, can be carried out together with the items arrayed on panels. The mass fabrication on panels may then be followed by an operation to singulate the assemblies.

Through such an assembly, there may be multiple circuit assemblies 12 within each chamber 26, and there may be multiple chambers, 26 within each EM shield 10. Additionally, a given EM shield assembly may include or omit resistive material 60 for damping, and may include or omit conductive assemblies 39.

Accordingly, while embodiments of circuit structures have been particularly shown and described with reference to the foregoing disclosure, many variations may be made therein. Other combinations and sub-combinations of features, functions, elements and/or properties may be used. Such variations, whether they are directed to different combinations or directed to the same combinations, whether different, broader, narrower or equal in scope, are also regarded as included within the subject matter of the present disclosure. The foregoing embodiments are illustrative, and no single feature or element is essential to all possible combinations that may be claimed in this or later applications. The claims, accordingly, define inventions disclosed in the foregoing disclosure. Where the claims recite “a” or “a first” element or the equivalent thereof, such claims include one or more such elements, neither requiring nor excluding two or more such elements. Further, ordinal indicators, such as first, second or third, for identified elements are used to distinguish between the elements, and do not indicate a required or limited number of such elements, and do not indicate a particular position or order of such elements unless otherwise specifically stated.

The invention claimed is:

1. An EM shield assembly, comprising:
an electromagnetically conductive shield having a top and sides forming a chamber configured to enclose a circuit assembly when the shield is mounted on a substrate supporting the circuit assembly; a dielectric body extending along at least a portion of the shield;
a conductive assembly extending along the dielectric layer spaced from the shield layer, the conductive assembly being adapted to be connected to a circuit element on the substrate.

2. The EM shield assembly of claim 1, in which the dielectric body extends along the top and at least a first side of the shield, the conductive assembly including a conductive strip extending along the top of the shield, and a first via extending through the dielectric body along the first side of the shield, the via being connected to the conductive strip, and which, in combination with the conductive strip, forms a continuous circuit path along the dielectric body.

3. The EM shield assembly of claim 2, in which the via is adapted to be attached to the circuit element during mounting of the EM shield onto the substrate.

4. The EM shield assembly of claim 3 in which the circuit assembly includes the circuit element, the circuit element is adapted to carry electrical current, and the conductive assembly is disposed interiorly of the shield layer.

5. The EM shield assembly of claim 4 further comprising a second via spaced from the first via, connected to the conductive strip, and conductively attached to an electrical conductor extending outside of the chamber.

6. The EM shield assembly of claim 1, in which the shield includes an opening providing access through the shield to the conductive assembly.

7. The EM shield assembly of claim 1, in which the dielectric body includes an interior surface at least partially covered with a resistive material capable of damping resonances in the chamber.

8. The EM shield assembly of claim 7, in which the resistive material is a resistive film.

9. The EM shield assembly of claim 7, in which the resistive material is applied to the interior surface in a pattern.

10. The EM shield assembly of claim 9, in which the pattern is a uniform pattern having a predetermined ratio of open areas without resistive material and covered areas with resistive material.

11. A circuit structure comprising:
a substrate;
a circuit assembly mounted on the substrate;
an enclosure mounted on the substrate and defining a chamber substantially enclosing the circuit assembly, with an edge extending along the substrate, the enclosure including an electromagnetic shield substantially enclosing the chamber, and a conductive strip extending along and electrically isolated from the electromagnetic shield; and
a circuit element mounted on the substrate and conductively coupled to the conductive strip.

12. The circuit structure of claim 11, in which the shield forms an exterior layer comprising an electromagnetically conductive material enclosing the conductive strip.

13. The circuit structure of claim 11 in which the enclosure includes a first dielectric layer separating the shield and the conductive strip.

14. The circuit structure of claim 13, in which the enclosure further includes a second dielectric layer, with the conductive strip disposed at least partially between the first and second dielectric layers.

15. The circuit structure of claim 14, in which the second dielectric layer includes an interior surface facing the chamber, the enclosure further including a layer of resistive material on the interior surface.

16. The circuit structure of claim 15, in which the resistive layer is distributed in a pattern having regularly spaced open spaces.

17. The circuit structure of claim 11, in which the shield has an opening adjacent to a first conductive strip end, and the conductive strip has a second end coupled to the circuit assembly, the circuit structure further comprising a conductor mounted on the substrate outside of the enclosure and connected to the one conductive strip end for conducting current between the circuit assembly and the exterior of the enclosure.

18. A circuit structure comprising:
a substrate;
a circuit assembly mounted on the substrate;
an enclosure mounted on the substrate and defining a chamber substantially enclosing the circuit assembly, the enclosure including an electromagnetic shield substantially enclosing the chamber, and a layer of resistive material capable of damping resonances in the chamber, the resistive layer extending along and electrically isolated from the electromagnetic shield.

19. The circuit structure of claim 18, in which the shield includes a layer of electromagnetically conductive material enclosing the resistive layer.

20. The circuit structure of claim 18 in which the enclosure includes a dielectric layer separating the shield and the resistive layer.

21. The circuit structure of claim 18, in which the resistive layer is distributed in a pattern having regularly spaced open spaces.

22. The circuit structure of claim 18, in which the resistive layer is a resistive film.
